(19) United States
(12) Patent Application Publication
(10) Pub. No.: US 2026/0123007 A1
(43) Pub. Date: Apr. 30, 2026

(54) SEMICONDUCTOR DEVICE

(71) Applicant: Samsung Electronics Co., Ltd., Suwon-si (KR)

(72) Inventors: Hyunwoo Kim, Suwon-si (KR); Dongwoo Kim, Suwon-si (KR); Chulsung Kim, Suwon-si (KR); Donghyun Roh, Suwon-si (KR); Taeyeon Shin, Suwon-si (KR); Hyoseok Choi, Suwon-si (KR)

(21) Appl. No.: 19/269,390

(22) Filed: Jul. 15, 2025

(30) Foreign Application Priority Data
Oct. 30, 2024 (KR) 10-2024-0150988

(51) Int. Cl. H10D 64/23; H10D 84/01; H10D 84/85

(52) U.S. Cl. CPC H10D 64/254; H10D 84/0186; H10D 84/851

(57) ABSTRACT

A semiconductor device includes: a semiconductor pattern; a plurality of channel structures each including a plurality of channel patterns on the semiconductor pattern; a plurality of gate structures crossing the plurality of channel structures; a plurality of insulating isolation patterns on regions corresponding to the plurality of gate structures, respectively, wherein the semiconductor pattern is divided into a plurality of pattern regions by the plurality of insulating isolation patterns; a plurality of contact blocks between the plurality of insulating isolation patterns; a contact via extending in the insulating isolation patterns to a first source/drain pattern, wherein a first pattern region penetrated by the contact via has a concentration of impurities higher than a concentration of impurities of the other pattern regions; and a metal-semiconductor compound layer between the first pattern region and the contact via.

### CROSS-REFERENCE TO RELATED APPLICATION(S)

This application claims the benefit of priority under 35 U.S.C. § 119 to Korean Patent Application No. 10-2024-0150988 filed on Oct. 30, 2024 in the Korean Intellectual Property Office, the disclosure of which is incorporated herein by reference in its entirety.

### BACKGROUND

Example embodiments of the present disclosure relate generally to a semiconductor device.

As demand for high performance, high speed, and/or multifunctionality of a semiconductor device increases, integration density of a semiconductor device has increased. In accordance with the trend toward higher integration of semiconductor devices, a semiconductor device having a backside power delivery network (BSPDN) structure in which power rails are disposed on a back surface of a wafer has been developed. However, due at least in part to a reduction in size of a planar metal-oxide-semiconductor field-effect transistor (MOSFET) device, interfacial resistance between a backside contact and a source/drain pattern of the MOSFET device may be increased.

### SUMMARY

An example embodiment of the present disclosure is to provide a semiconductor device having improved electrical properties and reliability.

According to an example embodiment of the present disclosure, a semiconductor device includes: a semiconductor pattern extending in a first direction; a plurality of channel structures arranged and spaced apart from each other in the first direction on the semiconductor pattern, wherein the plurality of channel structures include a plurality of channel patterns stacked and spaced apart from each other in a vertical direction; a plurality of gate structures crossing the plurality of channel structures in a second direction intersecting the first direction, respectively, and surrounding (i.e., extending around) the plurality of channel patterns; source/drain patterns between the plurality of channel structures on the semiconductor pattern and connected to side surfaces of the plurality of channel patterns; an insulating isolation layer on a lower surface of the semiconductor pattern; a plurality of insulating isolation patterns on regions corresponding to the plurality of gate structures on a lower surface of the insulating isolation layer and extending towards the plurality of gate structures, respectively, wherein the semiconductor pattern is divided into a plurality of pattern regions by the plurality of insulating isolation patterns; a plurality of contact blocks between the plurality of insulating isolation patterns on the lower surface of the insulating isolation layer; a contact via penetrating (i.e., extending in) the insulating isolation layer from at least one contact block among the plurality of contact blocks and extending to a source/drain pattern among the source/drain patterns, wherein the plurality of pattern regions include a first pattern region penetrated by the contact via and a second pattern region not penetrated by the contact via, and the first pattern region has a concentration of impurities higher than a concentration of impurities of the second pattern region; and a metal-semiconductor compound layer between the first pattern region and an adjacent source/drain pattern and the contact via.

According to an example embodiment of the present disclosure, a semiconductor device includes a semiconductor pattern extending in a first direction; a device isolation layer on opposing side surfaces of the semiconductor pattern, extending in the first direction; a plurality of channel structures arranged and spaced apart from each other in the first direction on the semiconductor pattern; a plurality of gate structures intersecting the plurality of channel structures in a second direction intersecting the first direction; source/drain patterns between the plurality of channel structures on the semiconductor pattern, and including a first epitaxial layer having a first concentration of impurities and a second epitaxial layer on the first epitaxial layer and having a second concentration of impurities higher than the first concentration of impurities; an insulating isolation layer on a lower surface of the semiconductor pattern; a plurality of insulating isolation patterns in regions corresponding to the plurality of gate structures on a lower surface of the insulating isolation layer, respectively, extending toward the plurality of gate structures, respectively, and dividing the semiconductor pattern into a plurality of pattern regions; a plurality of contact blocks between the plurality of insulating isolation patterns on the lower surface of the insulating isolation layer; a contact via penetrating the insulating isolation layer from at least one contact block among the plurality of contact blocks and extending to an adjacent source/drain pattern among the source/drain patterns, wherein the plurality of pattern regions include a first pattern region penetrated by the contact via and a second pattern region not penetrated by the contact via; and a contact epitaxial layer between the first pattern region and the adjacent source/drain patterns and the contact vias, and having a third concentration of impurities higher than the first concentration of impurities; a metal-semiconductor compound layer between the contact epitaxial layer and the contact via, and including the same semiconductor element as a semiconductor element of the contact epitaxial layer; and an interconnection structure on lower surfaces of the plurality of contact blocks and the plurality of insulating isolation patterns, and electrically connected to the at least one contact block.

According to an example embodiment of the present disclosure, a semiconductor device includes a semiconductor pattern extending in a first direction; a device isolation layer on opposing side surfaces of the semiconductor pattern extending in the first direction; a plurality of channel structures arranged and spaced apart from each other on the semiconductor pattern in the first direction; a plurality of gate structures intersecting the plurality of channel structures in a second direction intersecting the first direction; first and second source/drain patterns between the plurality of channel structures on the semiconductor pattern; an interlayer insulating layer on the device isolation layer and extending around the plurality of gate structures and the first and second source/drain patterns; an insulating isolation layer on a lower surface of the semiconductor pattern; a plurality of insulating isolation patterns on regions corresponding to the plurality of gate structures on a lower surface of the insulating isolation layer, penetrating the insulating isolation layer and extending toward the plurality of gate structures, respectively, wherein the semiconductor pattern is divided into a plurality of pattern regions by the plurality of insulating isolation patterns; a plurality of contact blocks between the plurality of insulating isolation patterns on the lower surface of the insulating isolation layer; a contact via penetrating the insulating isolation layer from a contact block adjacent to the plurality of contact blocks among the plurality of contact blocks and extending to the first source/drain pattern, wherein the plurality of pattern regions include a first pattern region penetrated by the contact via and a second pattern region not penetrated by the contact via, and the first pattern region has a concentration of impurities higher than a concentration of impurities of the second pattern region; an upper contact penetrating the interlayer insulating layer and connected to the second source/drain pattern; a metal-semiconductor compound layer between the first pattern region and the first source/drain pattern and the contact via; a first interconnection structure on the interlayer insulating layer and electrically connected to the upper contact; and a second interconnection structure on lower surfaces of the plurality of contact blocks, the plurality of insulating isolation patterns and the device isolation layer and electrically connected to the adjacent contact block.

### BRIEF DESCRIPTION OF DRAWINGS

The above and other aspects, features, and advantages of the present disclosure will be more clearly understood from the following detailed description, taken in combination with the accompanying drawings, wherein like reference numerals (when used) indicate corresponding elements throughout the several views, and in which:

FIG. 1 is a schematic plan diagram illustrating a semiconductor device according to an example embodiment of the present disclosure;

FIG. 2 is a schematic cross-sectional diagram illustrating a semiconductor device taken along line I-I′ in FIG. 1;

FIGS. 3A and 3B are schematic diagrams illustrating the semiconductor device in FIG. 1 taken along lines II1-II1′ and II2-II2′, respectively;

FIG. 4A is an enlarged schematic diagram illustrating a region “A” of the semiconductor device shown in FIG. 2;

FIG. 4B is an enlarged schematic diagram illustrating a region “B” of the semiconductor device shown in FIG. 3A;

FIGS. 5 and 6 are schematic cross-sectional diagrams illustrating a semiconductor die according to an example embodiment of the present disclosure;

FIGS. 7A to 12A and 7B to 12B are schematic cross-sectional diagrams illustrating intermediate processes (a process of forming an insulating isolation pattern) of a method of manufacturing a semiconductor device according to an example embodiment of the present disclosure; and

FIGS. 13A to 16A and 13B to 16B are schematic cross-sectional diagrams illustrating intermediate processes (a process of forming a backside contact structure) of a method of manufacturing a semiconductor device according to an example embodiment of the present disclosure.

### DETAILED DESCRIPTION

Hereinafter, embodiments of the present disclosure will be described as follows with reference to the accompanying drawings.

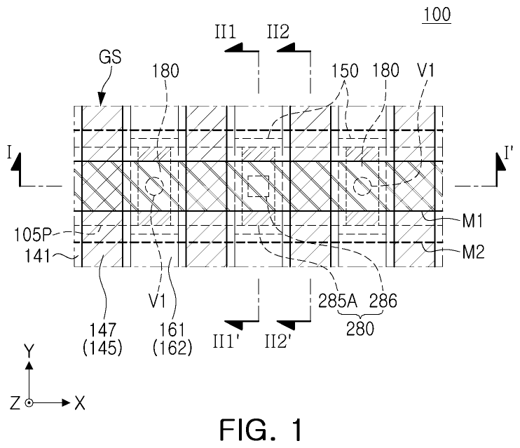

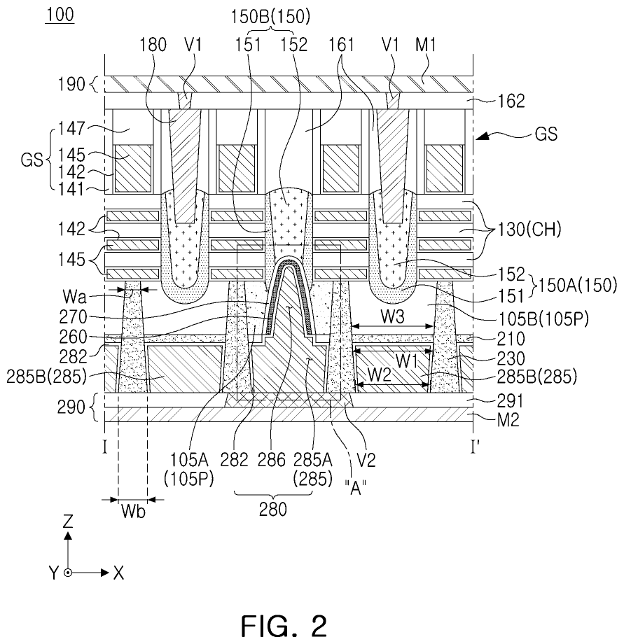

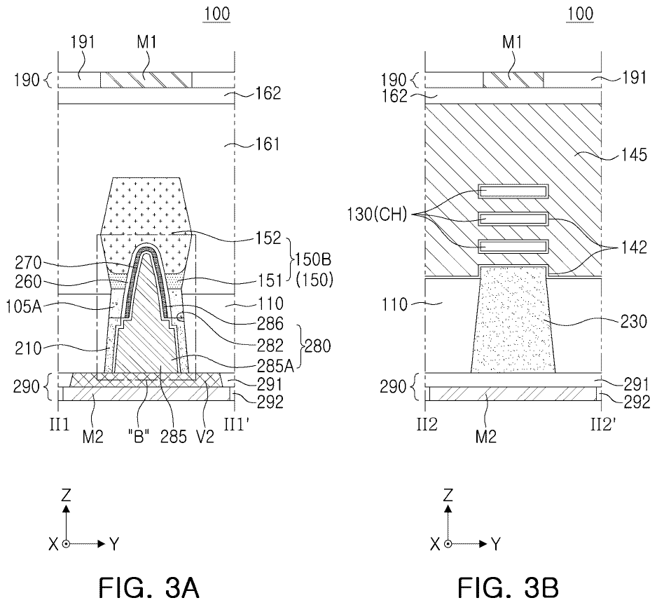

FIG. 1 is a schematic plan diagram illustrating a semiconductor device according to an example embodiment. FIG. 2 is a schematic cross-sectional diagram illustrating the semiconductor device shown in FIG. 1 taken along line I-I′. FIGS. 3A and 3B are schematic diagrams illustrating the semiconductor device shown in FIG. 1 taken along lines II1-II1′ and II2-II2′, respectively.

Referring to FIGS. 1, 2, 3A, and 3B, a semiconductor device 100 according to the example embodiment may include a semiconductor pattern 105P extending in a first direction (e.g., X-direction), a plurality of channel structures CH arranged and spaced apart from each other in the first direction (e.g., X-direction) on the semiconductor pattern 105P, a plurality of gate structures GS intersecting the plurality of channel structures CH in a second direction (e.g., Y-direction) intersecting the first direction (e.g., X-direction), and source/drain patterns 150 disposed between the plurality of channel structures CH.

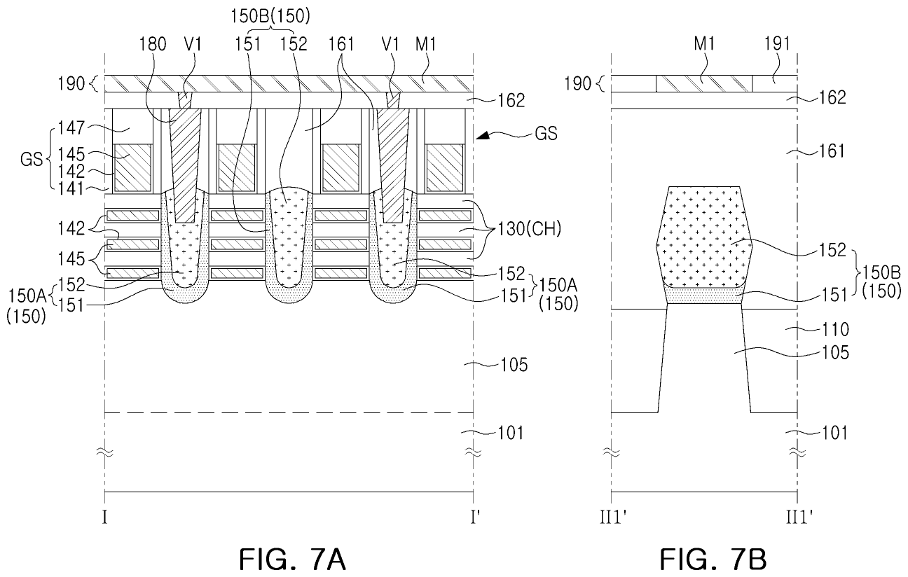

The semiconductor device 100 according to the example embodiment may include a semiconductor pattern 105P as a base structure for the gate structures GS and the source/drain patterns 150. In the example embodiment, the semiconductor pattern 105P may be a portion of the “active pattern 105” protruding and extending in the first direction (e.g., X-direction) on the substrate 101 before the substrate 101 is ground (see FIGS. 7A and 7B).

Referring to FIG. 3A, a device isolation layer 110 may be disposed between the semiconductor patterns 105P. The device isolation layer 110 may be disposed on both side surfaces of the semiconductor patterns 105P extending in the first direction (e.g., X-direction). An upper region of the semiconductor pattern 105P may be exposed from an upper surface of the device isolation layer 110.

As illustrated in FIGS. 2 and 3B, the channel structure CH may be arranged at a constant distance in the first direction (e.g., X-direction) on the semiconductor pattern 105P. In the example embodiment, the channel structure CH may include a plurality of channel patterns 130 stacked and spaced apart from each other in a vertical direction (e.g., Z direction), perpendicular to a surface of the substrate (101 in FIG. 7A) on the semiconductor pattern 105P. The plurality of channel patterns 130 may be provided as a channel structure CH of a transistor and may include, for example, at least one of silicon (Si), silicon germanium (SiGe), or germanium (Ge), although embodiments are not limited thereto. In some example embodiments, the plurality of channel patterns 130 may be a silicon semiconductor. In the example embodiment, the number of the plurality of channel patterns 130 may be three, but the number and the shape thereof may be varied.

As illustrated in FIGS. 1, 2 and 3B, the gate structure GS may include a gate electrode 145 extending in the second direction (e.g., Y-direction) and surrounding a plurality of channel patterns 130, a gate insulating film 142 disposed between the gate electrode 145 and the plurality of channel patterns 130, gate spacers 141 disposed on both (opposing) side surfaces of a portion of the gate electrode 145 positioned on an uppermost channel pattern of the plurality of channel patterns 130, and a gate capping layer 147 disposed on the gate electrode 145 between the gate spacers 141. The term “surrounding (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

The gate electrode 145 may include a conductive material. For example, the gate electrode 145 may include at least one of W, Ti, Ta, Mo, TiN, TaN, WN, TiON, TiAlC, TiAlN, or TaAlC. In some example embodiments, the gate electrode 145 may include a semiconductor material, such as doped polysilicon. At least one of the gate electrodes 145 may include a multilayer structure formed of different materials.

The gate insulating film 142 may include a dielectric material. For example, the gate insulating film 142 may include an oxide, a nitride, or a high dielectric constant (high-κ) material. The high dielectric constant material may refer to a dielectric material having a dielectric constant higher than that of silicon oxide (SiO₂). The high-κ material may be, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). In some example embodiments, the gate insulating film 142 may include two or more different dielectric films.

The gate spacers 141 may include an insulating material. For example, the gate spacers 141 may include at least one of silicon oxide, silicon nitride, or silicon oxynitride. In some example embodiments, the gate spacers 141 may include multilayer structures formed of different materials. The gate capping layer 147 may include, for example, silicon nitride, silicon oxynitride, silicon carbon nitride, or silicon oxycarbonitride.

Referring to FIG. 2, the semiconductor device 100 according to the example embodiment may include source/drain patterns 150 connected to both (opposing) side surfaces of the plurality of channel patterns 130, which may be channel regions on both sides of the gate structures GS, respectively. In the example embodiment, the semiconductor pattern 105P portion positioned on both sides of the gate structures GS may have recessed regions, and the source/drain patterns 150 may be disposed in the recessed regions of the semiconductor pattern 105P.

Referring to FIGS. 2 and 3A, the source/drain patterns 150 employed in the example embodiment may include a first epitaxial layer 151 and a second epitaxial layer 152 disposed on the first epitaxial layer 151. In the example embodiment, the first epitaxial layer 151 may be in direct contact with side surfaces of the plurality of channel patterns 130. In the example embodiment, the first epitaxial layer 151 and the second epitaxial layer 152 may include different materials. The first epitaxial layer 151 and the second epitaxial layer 152 may include different types of impurities or the same impurities at different concentrations.

In the case of a P-type MOSFET, the first and second epitaxial layers 151 and 152 may include SiGe having different Ge content (e.g., the second epitaxial layer 152 may have a higher Ge content), or the first and second epitaxial layers 151 and 152 may include Si and SiGe, respectively. In some example embodiments, the first and second epitaxial layers 151 and 152 may be doped with P-type impurities, for example, the P-type impurities may include at least one of B, C, Al, Ga, or In. The first epitaxial layer 151 may include P-type impurities at a first concentration, and the second epitaxial layer 152 may include P-type impurities at a second concentration greater than the first concentration.

In the case of an N-type MOSFET, both the first and second epitaxial layers 151 and 152 may include Si, and the first epitaxial layer 151 and the second epitaxial layer 152 may include different types of impurities or the same impurities at different concentrations. For example, the N-type impurities may include at least one of P, As, Sb, or Bi. The first epitaxial layer 151 may include N-type impurities at a first concentration, and the second epitaxial layer 152 may include N-type impurities at a second concentration greater than the first concentration.

In the example embodiment, the source/drain patterns 150 may include first source/drain patterns 150A connected to an upper contact structure 180 and second source/drain patterns 150B connected to a lower contact structure 280.

Specifically, the semiconductor device 100 according to the example embodiment may include an upper contact structure 180 connected to a first interconnection structure 190 on a front side of the semiconductor device 100 and a lower contact structure 280 connected to a second interconnection structure 290 on a back side of the semiconductor device 100. For example, the first interconnection structure 190 may be configured to include a signal line connected to the first source/drain patterns 150A of the semiconductor device 100 through the upper contact structure 180, and the second interconnection structure 290 may be configured to include a power line connected to the second source/drain patterns 150B of the semiconductor device 100 through the lower contact structure 280.

In the example embodiment, the upper contact structure 180 may be connected to the first source/drain patterns 150A between adjacent gate structures GS, and the lower contact structure 280 may be connected to the first source/drain patterns 180A between adjacent insulating isolation patterns 230. The upper and lower contact structures employed in the example embodiment will be described in greater detail below.

The semiconductor device 100 according to the example embodiment may further include a first interlayer insulating layer 161 disposed on the device isolation layer 110 to cover the source/drain patterns 150, that is, the first and second source/drain patterns 150A and 150B, and a second interlayer insulating layer 162 disposed on the first interlayer insulating layer 161 to cover the gate structure GS as illustrated in FIGS. 2 and 3B. The term “cover” (or “covering,” or like terms), as may be used herein, is intended to broadly refer to an element, structure or layer that is on or over another element, structure or layer, either directly or with one or more other intervening elements, structures or layers therebetween. For example, the first and second interlayer insulating layers 161 and 162 may include spin-on hardmask (SOH), flowable oxide (FOX), tonen silazen (TOSZ), undoped silica glass (USG), borosilica glass (BSG), phosphosilicate glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD) oxide or combinations thereof. Each of the first and second interlayer insulating layers 161 and 162 may be formed using chemical vapor deposition, a flowable CVD process, or a spin coating process, although embodiments are not limited thereto.

In the example embodiment, the upper contact structure 180 may penetrate (i.e., extend in or through) the first interlayer insulating layer 161 in the vertical direction (Z-direction) and may be connected to the first source/drain pattern 150A. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. The upper contact structure 180 may extend from an upper surface of the first source/drain pattern 150A into an internal region thereof.

Each of the upper contact structures 180 may include a contact plug and a conductive barrier surrounding the contact plug. For example, the contact plug may include Cu, Co, Mo, Ru, W, or an alloy thereof. For example, the conductive barrier may include Ta, TaN, Mn, MnN, WN, Ti, TiN, or a combination thereof.

As illustrated in FIG. 2, an insulating isolation layer 210 may be disposed on a lower surface of the semiconductor pattern 105P. A plurality of insulating isolation patterns 230 may be disposed in regions corresponding to a plurality of gate structures GS on a lower surface of the insulating isolation layer 210, respectively. The plurality of insulating isolation patterns 230 may have a structure extending in the vertical direction (e.g., in the Z direction). The plurality of insulating isolation patterns 230 may define spaces for contact blocks 285 on the lower surface of the insulating isolation layer 210.

Each of the plurality of insulating isolation patterns 230 may penetrate the insulating isolation layer 210 and may extend, vertically upward, toward the plurality of gate structures GS, respectively. By the extending portion, the semiconductor pattern 105P may be divided into a plurality of pattern regions 105A and 105B. For example, at least one of the insulating isolation layer 210 and the insulating isolation patterns 230 may include silicon nitride, silicon oxynitride, aluminum nitride, or aluminum oxynitride. In some example embodiments, the insulating isolation layer 210 and the insulating isolation patterns 230 may include the same insulating material.

Each of the plurality of contact blocks 285 may be disposed in a space between an adjacent pair of insulating isolation patterns 230 of the plurality of insulating isolation patterns 230 on a lower surface of the insulating isolation layer 210. The plurality of contact blocks 285 may be positioned below the source/drain patterns 150, respectively, and may be used as one portion of a potential lower contact structure for the source/drain patterns 150. As described above, in the example embodiment, the contact blocks 285 may be used as the lower contact structure 280 together with contact vias 286 extending therefrom. The contact blocks 280 employed in the example embodiment may be referred to as “active contact blocks 280A” participating in an operation of a transistor and ‘dummy contact blocks 280B’ not participating in an operation of the transistor.

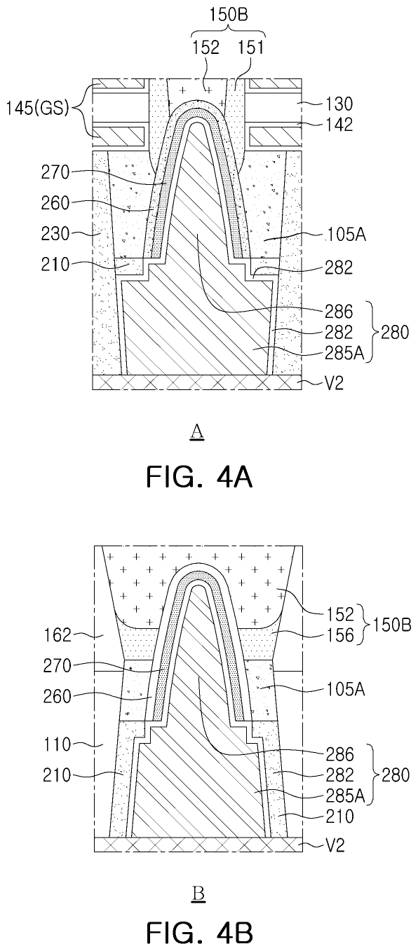

The lower contact structure 280 employed in the example embodiment may include at least one contact block 285A of the contact blocks 285, and a contact via 286 extending from the at least one contact block 285A to the second source/drain pattern 150B. The contact via 286 may extend from the at least one contact block 285A to the adjacent second source/drain pattern 150B of the source/drain patterns 150 by penetrating the insulating isolation layer 210. The contact via 286 may be connected to the second epitaxial layer 152 through the first epitaxial layer 151 to lower contact resistance (see FIG. 4A).

In the example embodiment, the plurality of pattern regions may be classified as a first pattern region 105A through which the contact via 286 penetrates, and second pattern regions 105B through which the contact via 286 does not penetrate.

A semiconductor device 100 according to the example embodiment may include a contact epitaxial layer 260 and a metal-semiconductor compound layer 270 disposed between a first pattern region 105A and a second source/drain pattern 150B and a contact via 286. The contact epitaxial layer 260 may be disposed between the first pattern region 105A and the second source/drain pattern 150B and the metal-semiconductor compound layer 270, and the metal-semiconductor compound layer 270 may be disposed between the contact epitaxial layer 260 and the contact via 286. FIG. 4A is an enlarged schematic diagram illustrating a region “A” of the semiconductor device shown in FIG. 2, and FIG. 4B is an enlarged schematic diagram illustrating a region “B” of the semiconductor device shown in FIG. 3A.

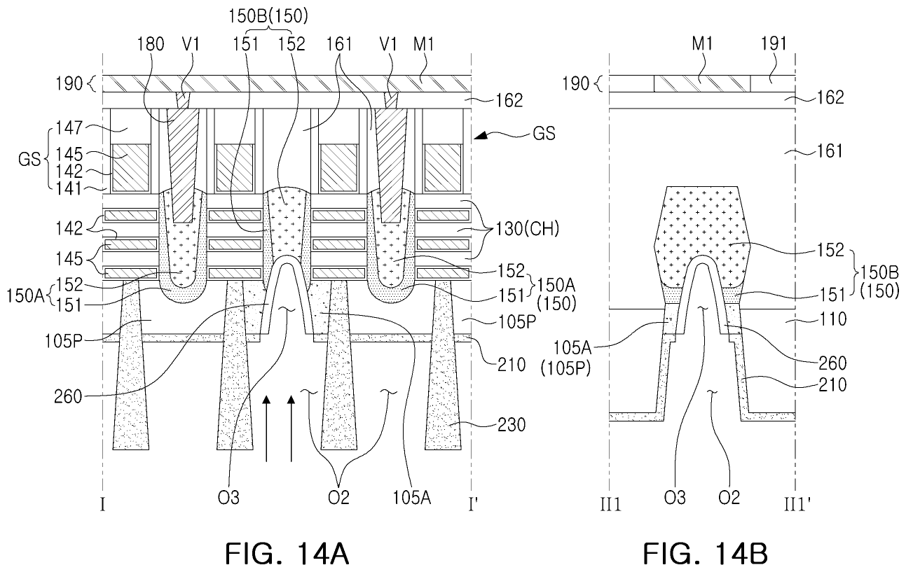

Referring to FIGS. 4A and 4B along with FIGS. 2 and 3A, the contact epitaxial layer 260 may be a high-concentration epitaxial layer re-grown on the semiconductor surface exposed to the contact hole; that is, exposed surfaces of the second source/drain pattern 150B and the first pattern region 105A (see FIG. 14). The term “exposed” (or “exposes,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. The contact epitaxial layer 260 employed in the example embodiment may be included to lower contact resistance of the contact via 286 and the second source/drain pattern 150B (particularly, the first epitaxial layer 151).

The contact epitaxial layer 260 may have a concentration of impurities at least higher than impurities of the first epitaxial layer 151. For example, the contact epitaxial layer 260 may have a concentration of impurities in the range of 10²⁰/cm³ to 10²²/cm³. Here, a concentration of impurities of the first epitaxial layer 151 may be defined as a concentration of impurities before the contact epitaxial layer 260 is formed, but in the final structure, the impurities of the contact epitaxial layer 260 may at least partially diffuse into the first epitaxial layer 151, such that the concentration of impurities of the first epitaxial layer 151 may be understood as a concentration of impurities in a region far from the contact via 286 (e.g., a region adjacent to the uppermost channel layer).

The contact epitaxial layer 260 may include silicon or silicon germanium, and the impurities of the contact epitaxial layer 260 may have the same conductivity (e.g., N-type or P-type) as a conductivity of impurities of the second source/drain pattern 150B.

When the second source/drain pattern 150B is a P-type epitaxial layer, the contact epitaxial layer 260 may include silicon germanium and may include at least one P-type impurity of B, C, Al, Ga, or In. For example, the concentration of germanium may be 40 atm % to 70 atm %, and the P-type impurities may include a range of 5×10²⁰/cm³ to 5×10²¹/cm³.

When the second source/drain pattern 150B is an N-type epitaxial layer, the contact epitaxial layer 260 may include silicon and may include at least one N-type impurity of P, As, Sb, or Bi. For example, the N-type impurities may include a range of 5×10²⁰/cm³ to 1×10²²/cm³.

In the example embodiment, a high concentration of impurities contained in the contact epitaxial layer 260 may also diffuse into the first pattern region. The first pattern region 105A may have a concentration of impurities higher than that of the second pattern regions 105B. For example, the second pattern regions 105B may be intentionally undoped with impurities (e.g., less than 10¹⁶/cm³) or may have a low concentration of impurities (e.g., less than 10¹⁸/cm³). In some example embodiments, in the first pattern region 105A, a region adjacent to the contact epitaxial layer 260 may have a concentration of impurities higher than that of the other regions.

In the example embodiment, the metal-semiconductor compound layer 270 may be obtained from a portion of the contact epitaxial layer 260. The metal-semiconductor compound layer 270 may include the same semiconductor element as the semiconductor element of the contact epitaxial layer 260. For example, when the contact epitaxial layer 260 is silicon, the metal-semiconductor compound layer 270 may include a metal silicide. In some example embodiments, the metal-semiconductor compound layer 270 may include at least one metal selected from a group consisting of Ti, Co, Ni, Pt, Zr, Mo, and Sc.

In the example embodiment, in a cross-section of the semiconductor device 100 in the first direction (see FIG. 2), each of the plurality of insulating isolation patterns 230 may have a shape in which a width Wb, in the first direction (X-direction), of a portion adjacent to the second interconnection structure 290 is greater than a width Wa, in the first direction, of a portion adjacent to the plurality of gate structures GS. Since an etching process for the insulating isolation patterns 230 is performed at a relatively low temperature (e.g., 400° C. or less) so as to not adversely affect the metal component of the first interconnection structure 190, the etching process may inevitably have a tapered structure. Accordingly, each of the contact blocks 285 defined by the plurality of insulating isolation patterns 230 may have a shape in which a width W2, in the first direction (X-direction), of the portion adjacent to the second interconnection structure 290 is smaller than a width W1, in the first direction, of the portion adjacent to the insulating isolation layer 210.

The semiconductor device 100 employed in the example embodiment may further include a conductive barrier 282 disposed between the insulating isolation layer 210 and the plurality of contact blocks 285. In the lower contact structure 280, the conductive barrier 282 may extend to a surface of at least one contact via 286.

The contact via 286 may include the same metal material as that of the first portion 285A of the plurality of contact blocks 285. Each of the plurality of contact blocks 285 may include the same metal material as that of the contact via 286.

For example, the contact via 286 and the contact blocks 285 may include W, Mo, Co, or Ru. For example, the conductive barrier 282 may include Ta, TaN, Mn, MnN, WN, Ti, or TiN.

The semiconductor device 100 according to the example embodiment may have a dual-surface interconnection structure including the first interconnection structure 190 and the second interconnection structure 290. The first interconnection structure 190 may be provided on an upper surface of the semiconductor device 100, and the second interconnection structure 290 may be provided on a lower surface of the semiconductor device 100.

The first interconnection structure 190 may include a first interconnection insulating layer 191 and a first interconnection line M1 disposed within the first interconnection insulating layer 191. The first interconnection line M1 may be connected to the upper contact structure 180 by a first via V1 penetrating the second interlayer insulating layer 162.

Similarly, the second interconnection structure 290 may include second interconnection insulating layers 291 and 292, and a second interconnection line M2 disposed within the second interconnection insulating layers 291 and 292. In the example embodiment, the second interconnection line M2 may be electrically insulated from the dummy contact block 280B by the second interconnection insulating layer 291, and may connected to the active contact block 280A of the lower contact structure 280 by a second via V2 penetrating the second interconnection insulating layer 291.

In this structure, power for element operation may be supplied to the first source/drain pattern 150A through the second interconnection line M2 and the lower contact structure 280 connected thereto, thereby simplifying the first interconnection line M1.

For example, the first and second interconnection insulating layers 191, 291, and 292 may include a low-dielectric material such as silicon oxide, silicon oxynitride, SiOC, or SiCOH. For example, the first and second interconnection lines M1 and M2 and the first and second vias V1 and V2 may include copper or a copper-containing alloy.

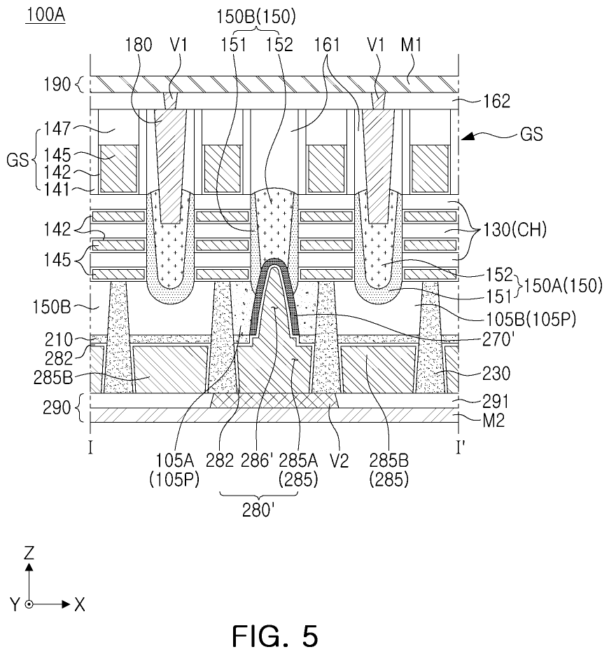

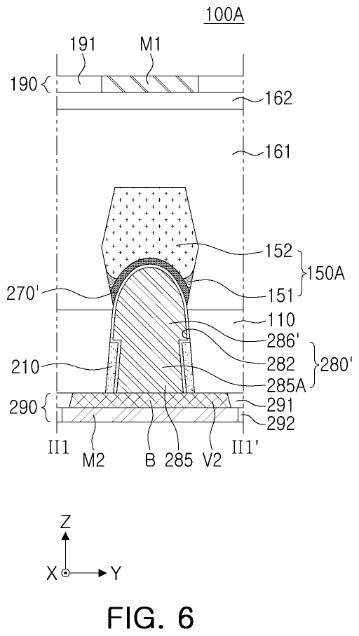

FIGS. 5 and 6 are schematic cross-sectional diagrams illustrating a semiconductor die according to an example embodiment.

Referring to FIGS. 5 and 6, the semiconductor device 100A according to the example embodiment may be understood as being similar to the semiconductor device 100 illustrated in FIGS. 1 to 4B, other than the configuration in which only a metal-semiconductor compound layer 270′ is disposed between the first pattern region 105A and the second source/drain pattern 150B and a contact via 286′ without a contact epitaxial layer, and the configuration in which the width of the contact via 286′ in the second direction (e.g., Y-direction) is larger. Also, the components in the example embodiment may be understood by referring to the description of the same or similar components of the semiconductor device 100 illustrated in FIGS. 1 to 4B, unless otherwise indicated.

In the example embodiment, the lower contact structure 280′ may include contact blocks 285 and contact vias 286′ extending from a contact block 285A in the vertical direction (Z-direction) to the second source/drain pattern 150B, similarly to the aforementioned example embodiment. Referring to FIG. 6, the pattern region 105A portion may not remain on both (opposing) sides of the contact via 286′. A width of the contact via 286′ in the second direction (e.g., Y-direction) may be defined by a width of the pattern region 105A. The width of the contact via 286′ may be greater than the width of the contact via 286′ in the second direction (e.g., Y-direction) in the aforementioned example embodiment (see FIGS. 3A and 4A).

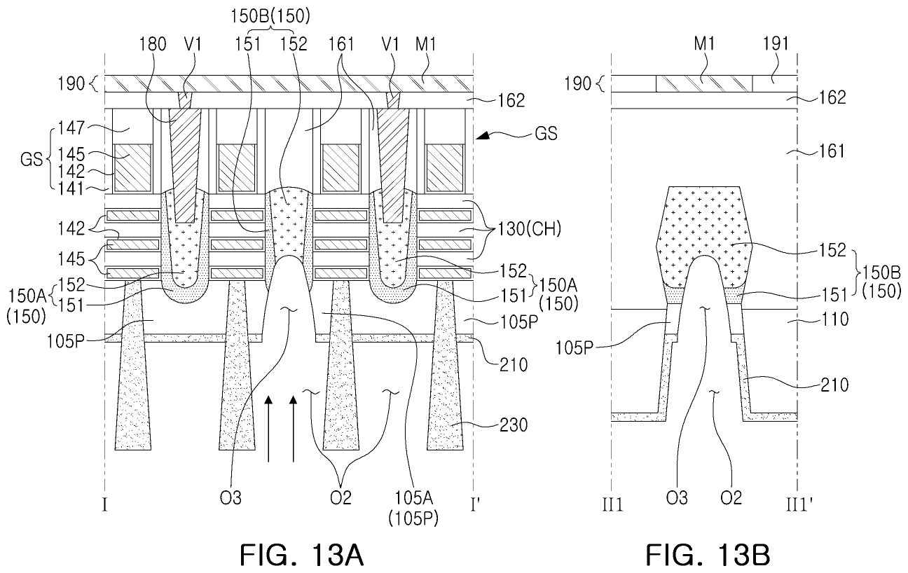

Specifically, in the process of forming a contact hole for the contact via 286′ (see the process in FIG. 13B), the semiconductor pattern portion positioned in the second direction (e.g., Y-direction) may be removed to expose the device isolation layer 110.

The semiconductor device 100A according to the example embodiment may include a metal-semiconductor compound layer 270′ without a contact epitaxial layer disposed between the first pattern region 105A and the second source/drain pattern 150B and the contact via 286. This structure may be formed the metal-semiconductor compound layer 270′ by metallizing most of the contact epitaxial layer.

The presence of the contact epitaxial layer may be confirmed by a concentration of impurities of surrounding components. In the example embodiment, the first pattern region 105A′ may have a concentration of impurities higher than that of the second pattern regions 105B. The high concentration of impurities contained in the contact epitaxial layer may also diffuse into the first pattern region 105A′. In some example embodiments, in the first pattern region 105A, a region adjacent to the contact epitaxial layer 260 may have a concentration of impurities higher than that of the other region.

Similarly, the impurities of the contact epitaxial layer 260 may diffuse into the first epitaxial layer 151. In the first epitaxial layer 151, a region adjacent to the contact via 286 may have a concentration of impurities greater than that of a region spaced apart from the contact via 286 (e.g., a region adjacent to the uppermost channel layer). As such, the contact via 286 may have improved contact resistance with the second source/drain pattern 150B, especially with the first epitaxial layer 151.

The features, functions and effects in the example embodiments may be understood in greater detail by describing a method of manufacturing a semiconductor device below.

FIGS. 7A to 12A and 7B to 12B are schematic cross-sectional diagrams illustrating intermediate processes (a process of forming an insulating isolation pattern) of a method of manufacturing a semiconductor device according to an example embodiment. FIGS. 7A to 12A are schematic cross-sections corresponding to FIG. 2, and FIGS. 7B to 12B are schematic cross-sections corresponding to FIG. 3A.

Referring to FIGS. 7A and 7B, gate-all-around (GAA) type transistor elements including a plurality of channel structures CH, a plurality of gate structures GS, and first and second source/drain patterns 150A and 150B may be formed on a substrate 101.

The semiconductor substrate 101 may include a semiconductor material, for example, a group IV semiconductor, a group III-V compound semiconductor, or a group II-VI semiconductor. For example, the group IV semiconductor may include silicon (Si), germanium (Ge), or silicon germanium (SiGe). The semiconductor substrate 101 may include, for example, a bulk wafer, an epitaxial layer, or a silicon on insulator (SOI) layer.

The plurality of channel structures CH may include a plurality of channel patterns 130 stacked and spaced apart from each other in a vertical direction perpendicular to the semiconductor pattern 105 and extending in the first direction (X-direction) parallel to the semiconductor pattern 105. The plurality of gate structures GS may be formed to cross the plurality of channel structures CH in the second direction, respectively and to surround (i.e., extend around) the plurality of channel patterns 130. The first and second source/drain patterns 150A and 150B may be disposed in a recess region extending from a region between the plurality of channel structures CH to a region of the semiconductor pattern 105 and may be connected to both side surfaces of the plurality of channel patterns 130 in the first direction, respectively.

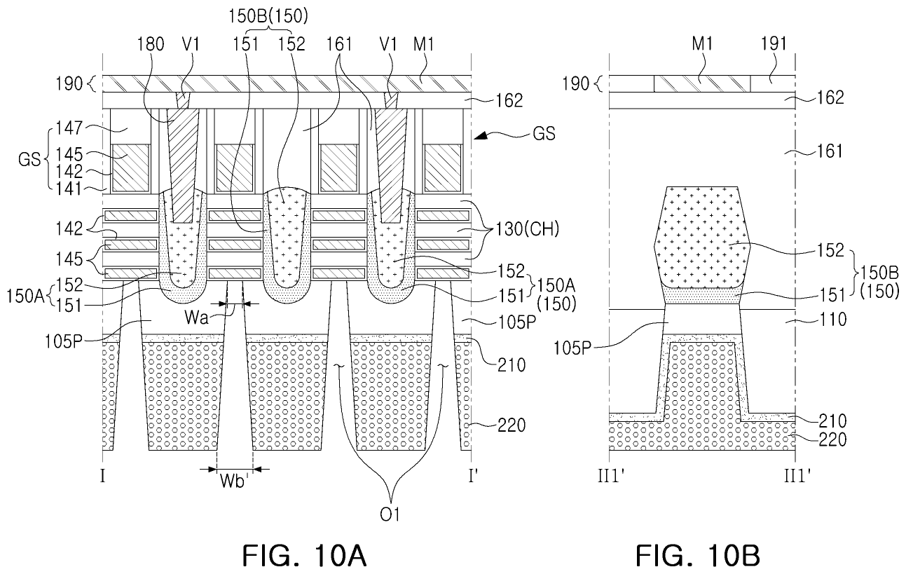

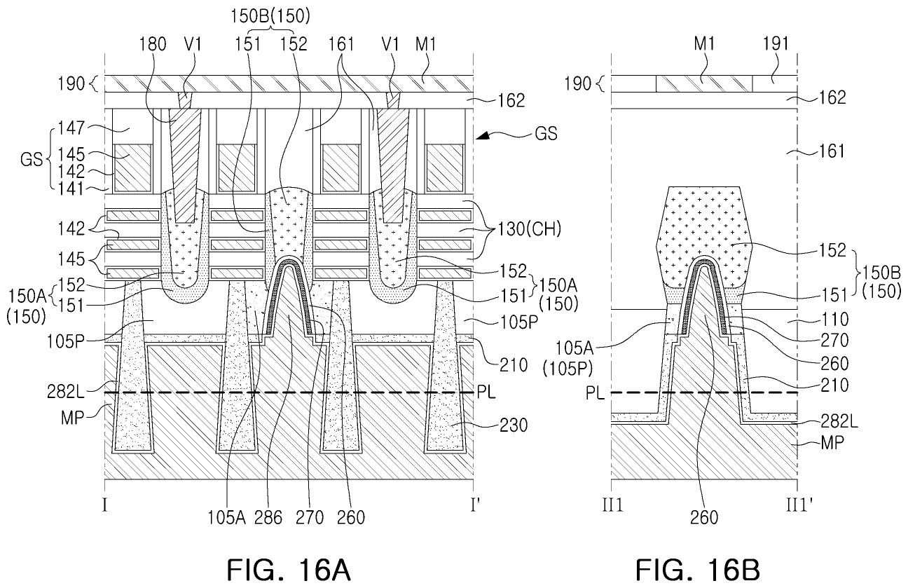

Also, a first interlayer insulating layer 161 covering the first and second source/drain patterns 150A and 150B may be formed between the plurality of gate structures GS, and an upper contact structure 180 penetrating (i.e., extending in or through) the first interlayer insulating layer 161 and connected to the first source/drain pattern 150A may be formed. Further, a second interlayer insulating layer 162 may be formed on the first interlayer insulating layer 161 to cover a plurality of gate structures GS, and a first interconnection structure 190 connected to the upper contact structure 180 may be formed. Since the first interconnection structure 190 is formed in advance in this process, there may be a limitation in terms of process conditions in which a subsequent process may need to be performed at a relatively low temperature (e.g., 400° C. or less) so as to not adversely affect the metal component of the first interconnection structure 190. For example, a side surface inevitably tapered in the process (see FIGS. 10A and 10B) of forming first openings O1 for an insulating isolation pattern may be formed, and to prevent pinhole defects, it may be necessary to form a conductive barrier 282L to a sufficient thickness (see FIGS. 16A and 16B).

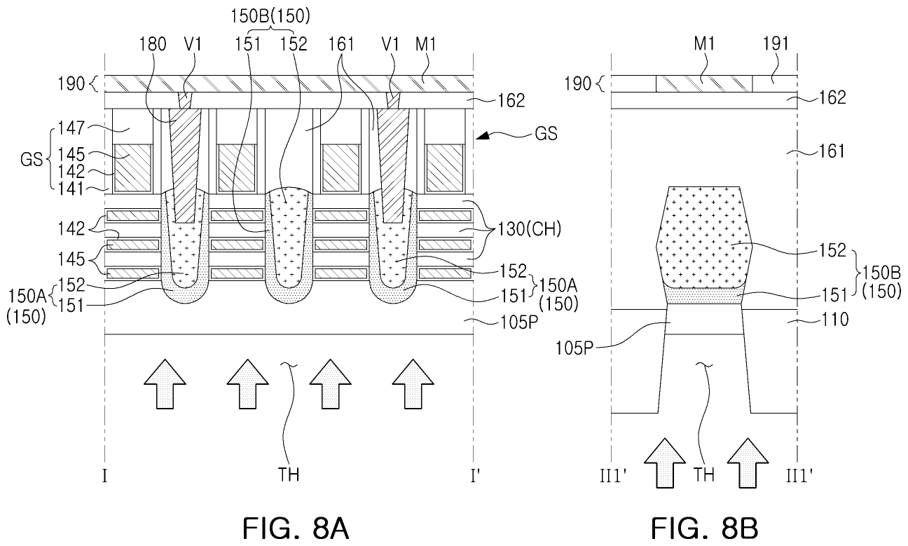

Thereafter, referring to FIGS. 8A and 8B, the semiconductor pattern 105P may partially remain by removing the substrate 101 (see FIGS. 7A and 7B).

The process may be performed in order as a process of removing the substrate 101 and a process of partially removing the semiconductor pattern 105P. First, the process of removing the substrate 101 may be performed by a polishing process (e.g., a chemical-mechanical polishing or planarization (CMP) process) and/or an etching process. The removing process may be performed until the device isolation layer 110 is exposed. Also, the semiconductor pattern 105 may be partially removed using a selective etching process, and therefore the semiconductor pattern 105P of a predetermined thickness may remain. Even after the process, the remaining semiconductor pattern 105P may extend in the first direction, and as illustrated in FIG. 8B, the remaining semiconductor pattern 105P may have a lower surface further recessed than the exposed lower surface of the device isolation layer 110 in the cross-section in the second direction. The device isolation layer 110 may define a space TH from which the semiconductor pattern 105 is removed.

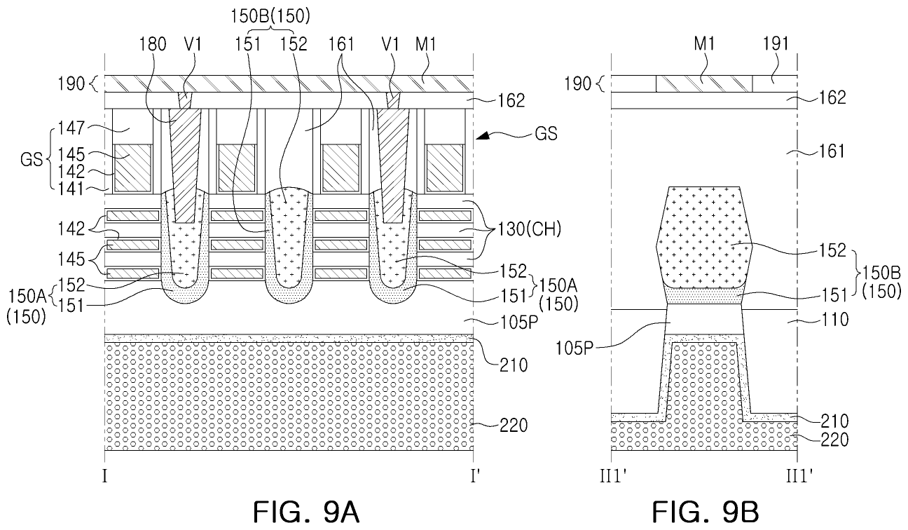

Thereafter, referring to FIGS. 9A and 9B, an insulating isolation layer 210 may be formed on a lower surface of the remaining semiconductor pattern 105P, and an insulating base layer 220 may be formed on the insulating isolation layer 210. Depending on a cross-sectional thickness of the insulating isolation layer 210, the insulating isolation layer 210 may be conformal with the lower surface of the remaining semiconductor pattern 105P. The term “conformal” (or like terms), as may be used herein in the context of a material layer or coating, is intended to refer broadly to a material layer or coating having a substantially uniform cross-sectional thickness relative to the contour of a surface to which the material layer is applied.

First, the insulating isolation layer 210 may be formed on the semiconductor pattern 105 and the device isolation layer 110. As illustrated in FIG. 9B, the insulating isolation layer 210 may be formed along the recessed lower surface of the semiconductor pattern 105, the sidewall exposed to the space TH, and the lower surface of the device isolation layer 110. The insulating isolation layer 210 may be formed relatively conformally using a deposition process such as chemical vapor deposition (CVD). For example, the insulating isolation layer 210 may be silicon nitride, silicon oxynitride, aluminum nitride, aluminum oxide, or aluminum oxynitride.

The insulating base layer 220 may be formed on the insulating isolation layer 210 to fill the space TH from which the semiconductor pattern 105 is partially removed. The term “fill” (or “fills,” or like terms) is intended to refer to either completely filling a defined space (e.g., the space TH) or partially filling the defined space; that is, the defined space need not be entirely filled but may, for example, be partially filled or have voids or other spaces throughout. The insulating base layer 220 may include, for example, SOH, FOX, TOSZ, USG, BSG, PSG, BPSG, PETEOS, FSG, HDP oxide, PEOX, FCVD oxide, or a combination thereof. For example, the insulating base layer 220 may be formed using a chemical vapor deposition (CVD) process, a flowable CVD process, or a spin coating process. In some example embodiments, a planarization process for the lower surface of the insulating base layer 220 may be further performed.

Thereafter, referring to FIGS. 10A and 10B, a plurality of first openings O1 may be formed by partially removing the insulating base layer 220 and the insulating isolation layer 210.

The plurality of first openings O1 may be formed in a region corresponding to a plurality of gate structures GS in the insulating base layer 220. The plurality of first openings O1 may be formed by etching from the insulating base layer 220 to the semiconductor pattern 105P. As such, the plurality of first openings O1 may penetrate through the insulating isolation layer 210 and the semiconductor pattern 105P and may extend vertically to the lower surface of each gate structure GS.

In the example embodiment, the plurality of first openings O1 may be divided by a plurality of pattern regions 105A and 105B. The plurality of pattern regions 105A and 105B may be arranged in the first direction to be positioned below the source/drain patterns 150, respectively. Here, the plurality of pattern regions may be formed of a portion of the same semiconductor pattern, and may be divided into the first pattern region 105A positioned on the second source/drain pattern 105B and the second pattern region 105B positioned on the first source/drain pattern 105A.

The etching process for the plurality of first openings O1 may be performed at a relatively low temperature (e.g., 400° C. or less) so as to not adversely affect the metal component of the first interconnection structure 190, such that it may be difficult to form an almost vertical structure. Accordingly, each of the plurality of first openings O1 may inevitably have a tapered side surface. As illustrated in FIG. 10A, each of the plurality of first openings O1 may have a shape in which a width Wb′, the first direction (X-direction), of a portion adjacent to a lower surface of the insulating base layer 220 may be larger than a width Wa, in the first direction, of a portion adjacent to the plurality of gate structure GS. Also, due to the difference in an etching rate, an inner sidewall of the semiconductor layer 105 and an inner sidewall of the insulating base layer 220 may have different profiles (e.g., slope angle).

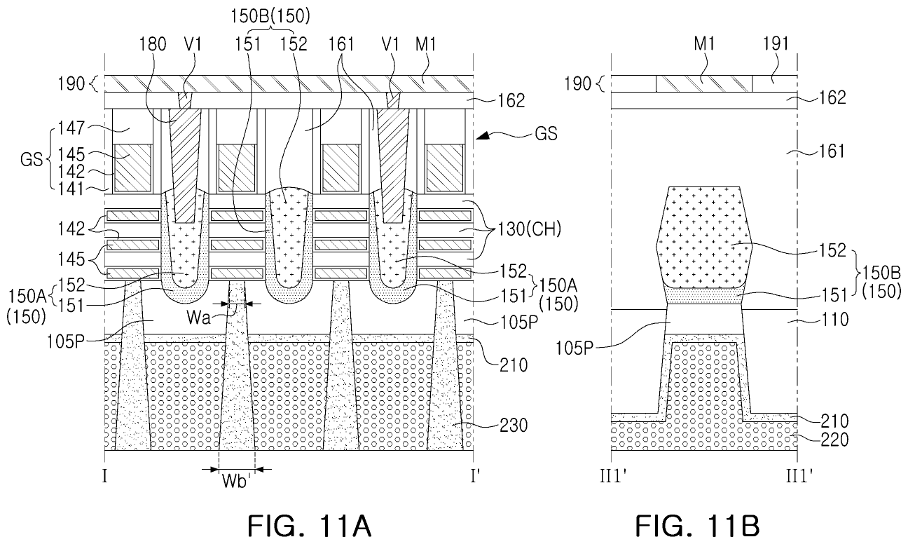

Thereafter, referring to FIGS. 11A and 11B, insulating isolation patterns 230 may be formed to at least partially fill the plurality of first openings O1, respectively.

In the example embodiment, a deposition process of forming insulating isolation patterns 230 in a plurality of first openings O1 may be performed. The process of depositing an insulating material may be performed such that the first opening O1 may be filled. For example, the insulating isolation patterns 230 may include silicon nitride or silicon oxynitride. In the insulating material deposition process of forming the plurality of insulating isolation patterns 230, a lower surface of the insulating base layer 220 may be formed to cover the lower surface, and additionally, through a polishing process, as illustrated in FIG. 11A, the lower surface of the insulating base layer 220 may be exposed and may have a surface substantially coplanar with the lower surface of the insulating isolation patterns 230.

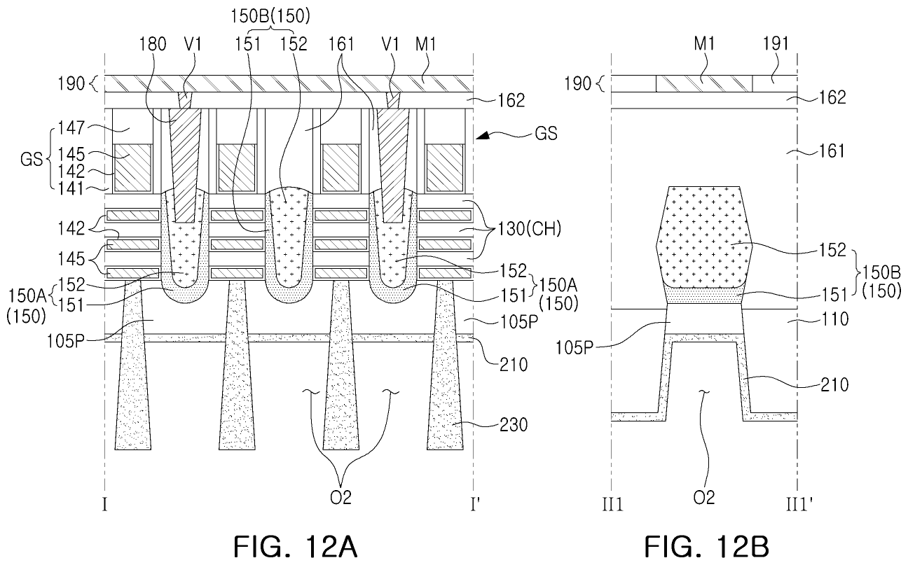

Thereafter, referring to FIGS. 12A and 12B, second openings O2 may be formed by removing the insulating base layer 220 (see FIGS. 11A and 11B).

The second openings O2 may substantially correspond to the space TH (see FIGS. 8A and 8B) from which the semiconductor pattern 105 is partially removed below each of the first and second source/drain patterns 150A and 150B. The insulating isolation layer 210 may be formed on an inner surface of the second openings O2 and a lower surface of the device isolation layer 110. In this removing process, the insulating isolation layer 210 may be used as an etch stop layer. A width of each of the second openings O2 in the first direction may be defined by a plurality of insulating isolation patterns 230, and a width of each of the second openings O2 in the second direction may be defined by the space TH in which the insulating isolation layer 210 is formed, that is, the insulating base layer 220 in the space (see FIG. 9B).

FIGS. 13A to 16A and 13B to 16B are schematic cross-sectional diagrams illustrating intermediate processes (a process of forming a backside contact structure) of a method of manufacturing a semiconductor device according to an example embodiment. Here, FIGS. 13A to 16A are schematic cross-sections corresponding to FIG. 2, and FIGS. 13A to 16B are schematic cross-sections corresponding to FIG. 3A.

Referring to FIGS. 13A and 13B, a third opening O3 connected to the second source/drain patterns 150B may be further formed in at least one second opening O2 among the second openings O2.

In this process, the second opening O2 may be formed in the first pattern region 105A positioned below the second source/drain patterns 150B. The third opening O3 connected to the second source/drain pattern 150B may be formed by removing a portion of the insulating isolation layer 210 exposed to the second opening O2 and partially removing the first pattern region 105A through the removed region. The second opening O2 may provide a space in which a contact via (“286” in FIG. 2) is formed, and the third openings O3 may provide a space in which a contact block (“285” in FIG. 2) is formed. Specifically, the second opening O2 formed by the third opening O3 may be provided as a space to form an active contact block 285A to be connected to the second source/drain pattern 150B, and the third opening O3 may be provided as a space to form a contact via 286. Also, the remaining second openings O2 may be provided as a region to form a dummy contact block 285B below the first source/drain patterns 150A.

Thereafter, referring to FIGS. 14A and 14B, a contact epitaxial layer 260 may be re-grown on the surface exposed by the third opening O3.

The surfaces of the first pattern region 105A and the second source/drain pattern 150B may be exposed by the third opening O3. The exposed surfaces may be provided as contact regions. Particularly, the surfaces of the second source/drain patterns 150B may include surfaces of the second epitaxial layer 152 and also surfaces of the first epitaxial layer 151. Particularly, the first epitaxial layer 151 may have a relatively low concentration of impurities and high resistance. Accordingly, In this process, a contact epitaxial layer 260 having high concentration impurities may be further formed to lower contact resistance with the second source/drain patterns 150B. The contact epitaxial layer 260 may include silicon or silicon germanium, and impurities of the contact epitaxial layer 260 may have the same conductivity as that of impurities of the second source/drain patterns 150B.

The contact epitaxial layer 260 may have a concentration of impurities higher than at least the impurities of the first epitaxial layer 151. For example, the contact epitaxial layer 260 may have a concentration of impurities in the range of 10²⁰/cm³ to 10²²/cm³. In an additional heat treatment in this process or a subsequent process similar thereto, the high concentration of impurities contained in the contact epitaxial layer 260 may also diffuse into the first pattern region 105A. The first pattern region 105A may have a concentration of impurities higher than the concentration of impurities of the second pattern regions 105B. Similarly, the high concentration of impurities contained in the contact epitaxial layer 260 may also diffuse into the second source/drain pattern 150B, particularly the first epitaxial layer 151, thereby at least partially increasing the concentration of impurities of the first epitaxial layer 151.

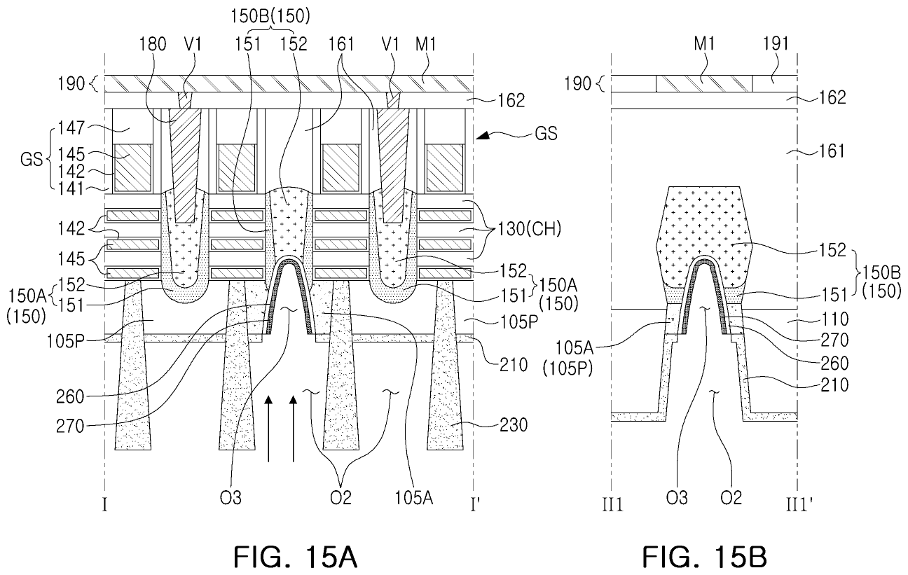

Thereafter, referring to FIGS. 15A and 15B, a portion region of the contact epitaxial layer 260 may be formed as a metal-semiconductor compound layer 270.

The metal-semiconductor compound layer 270 may be formed using a silicidation process. For example, after depositing a metal layer on the contact epitaxial layer 260, the metal-semiconductor compound layer 270 may be formed through an annealing process such as millisecond annealing. In this process, at least a portion of the contact epitaxial layer 260 may be changed to the metal-semiconductor compound layer 270. In the example embodiment, since the contact epitaxial layer 260 remains, both the contact epitaxial layer 260 and the metal-semiconductor compound layer 270 may be positioned on the contact interfacial surface. In some example embodiments (see FIGS. 5 and 6), almost the entirety of the contact epitaxial layer 260 may be changed to the metal-semiconductor compound layer 270, such that only the metal-semiconductor compound layer 270 may remain without the contact epitaxial layer 260.

Accordingly, the metal-semiconductor compound layer 270 may include the same semiconductor element as the semiconductor element of the contact epitaxial layer 260. In some example embodiments, the process of forming the metal-semiconductor compound layer 270 may be changed. For example, the annealing process during the silicidation process may be performed after the conductive barrier is formed on the metal layer.

For example, when the contact epitaxial layer 260 is silicon, the metal-semiconductor compound layer 270 may include a metal silicide. In some example embodiments, the metal-semiconductor compound layer 270 may include at least one metal selected from a group consisting of Ti, Co, Ni, Pt, Zr, Mo, or Sc.

Thereafter, referring to FIGS. 16A and 16B, by forming the second openings O2 and the third opening O3 with the conductive barrier 282L and the conductive material MP (or a contact plug), the lower contact structure 280 and the dummy contact block 285B (see FIG. 2) may be formed.

Before deposition of the conductive material MP, the conductive barrier 282L may be conformally formed along the surfaces exposed by the second openings O2 and the third opening O3. Since the conductive barrier 282L is formed at a relatively low temperature (e.g., 400° C. or less) so as to not adversely affect metal components of the first interconnection structure 190, it may be necessary to form the barrier to have a sufficient thickness to prevent pinhole defects. Accordingly, the second openings O2 and the third opening O3 may be filled to a predetermined level by the relatively high resistance conductive barrier 282L.

Thereafter, the conductive material MP may be formed on the second openings O2 such that the third opening O3 may be filled on the conductive barrier 282L. The deposition process of the conductive material MP may be performed by a CVD or PVD process. The conductive material MP may be filled in the third opening O3 and a contact via 286 connected to the exposed region of the second source/drain pattern 150B may be formed.

Thereafter, the conductive material MP and the conductive barrier 282 may be partially removed using a grinding process, and the lower surfaces of the insulating isolation patterns 230 may be exposed by grinding to a predetermined level PL. Accordingly, the contact blocks 285 may be isolated from each other by the insulating isolation patterns 230. The grinding process may be performed such that the thickness of the semiconductor device 100 may be reduced to a desired thickness. A second interconnection structure 290 connected to a contact block 285A of the lower contact structure 280 may be formed on the insulating isolation patterns 230 and the contact block 285.

According to the aforementioned example embodiments, by including a contact epitaxial layer having high concentration impurities on the surface of the source/drain patterns and the semiconductor pattern region, contact resistance with the lower contact structure may be improved. At least a portion of the contact epitaxial layer may be changed to a metal-semiconductor compound layer. In some example embodiments, the semiconductor pattern region may have a concentration of impurities higher than that of other semiconductor pattern regions.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a semiconductor pattern extending in a first direction;
a plurality of channel structures arranged and spaced apart from each other in the first direction on the semiconductor pattern, wherein the plurality of channel structures include a plurality of channel patterns stacked and spaced apart from each other in a vertical direction perpendicular to a surface of the semiconductor pattern;
a plurality of gate structures crossing the plurality of channel structures in a second direction intersecting the first direction, respectively, and extending around the plurality of channel patterns;
source/drain patterns on the semiconductor pattern between the plurality of channel structures and connected to side surfaces of the plurality of channel patterns;
an insulating isolation layer on a lower surface of the semiconductor pattern;
a plurality of insulating isolation patterns on regions corresponding to the plurality of gate structures on a lower surface of the insulating isolation layer and extending towards the plurality of gate structures, respectively, wherein the semiconductor pattern is divided into a plurality of pattern regions by the plurality of insulating isolation patterns;
a plurality of contact blocks on the lower surface of the insulating isolation layer and between the plurality of insulating isolation patterns;
a contact via extending through the insulating isolation layer from at least one contact block among the plurality of contact blocks to a first source/drain pattern among the source/drain patterns, wherein the plurality of pattern regions includes a first pattern region penetrated by the contact via and a second pattern region not penetrated by the contact via, and the first pattern region has a first concentration of impurities higher than a second concentration of impurities of the second pattern region; and
a metal-semiconductor compound layer between the first pattern region and the first source/drain pattern, and the contact via.

2. The semiconductor device of claim 1, further comprising:
an interconnection structure on lower surfaces of the plurality of contact blocks and the plurality of insulating isolation patterns, the interconnection structure electrically connected to at least one contact block of the plurality of contact blocks.

3. The semiconductor device of claim 1, further comprising:
a contact epitaxial layer between the first pattern region and the first source/drain pattern and the metal-semiconductor compound layer,
wherein the contact epitaxial layer includes a semiconductor element having a same conductivity as a conductivity of a semiconductor element of the metal-semiconductor compound layer, and the contact epitaxial layer includes impurities having a same conductivity as a conductivity of impurities of an adjacent source/drain pattern of the source/drain patterns.

4. The semiconductor device of claim 3, wherein, in the first pattern region, a concentration of impurities in a region in contact with the contact epitaxial layer is greater than a concentration of impurities in another region.

5. The semiconductor device of claim 3, wherein the contact epitaxial layer has a concentration of impurities in a range of about 10²⁰/cm³ to 10²²/cm³.

6. The semiconductor device of claim 3, wherein each of the source/drain patterns includes a first epitaxial layer having a first concentration of impurities and a second epitaxial layer on the first epitaxial layer and having a second concentration of impurities higher than the first concentration of impurities.

7. The semiconductor device of claim 6, wherein the contact epitaxial layer has a concentration of impurities higher than the first concentration of impurities.

8. The semiconductor device of claim 6, wherein, in the first epitaxial layer, a concentration of impurities in a region in contact with the contact epitaxial layer is greater than a concentration of impurities in another region.

9. The semiconductor device of claim 1, wherein each of the plurality of contact blocks includes a same metal material as that of the contact via.

10. The semiconductor device of claim 9, wherein the plurality of contact blocks and the contact via include tungsten (W), molybdenum (Mo), cobalt (Co), or ruthenium (Ru).

11. The semiconductor device of claim 1, further comprising:
a conductive barrier between the insulating isolation layer and the plurality of insulating isolation patterns and the plurality of contact blocks, and extending to a surface of the contact via.

12. The semiconductor device of claim 11, wherein the conductive barrier includes tantalum (Ta), tantalum nitride (TaN), manganese (Mn), manganese nitride (MnN), tungsten nitride (WN), titanium (Ti), or titanium nitride (TiN).

13. The semiconductor device of claim 1, wherein the metal-semiconductor compound layer includes at least one metal selected from a group consisting of titanium (Ti), cobalt (Co), nickel (Ni), platinum (Pt), zirconium (Zr), molybdenum (Mo), and scandium (Sc).

14. A semiconductor device, comprising:
a semiconductor pattern extending in a first direction;
a device isolation layer on opposing side surfaces of the semiconductor pattern and extending in the first direction;
a plurality of channel structures on the semiconductor pattern and spaced apart from each other in the first direction;
a plurality of gate structures intersecting the plurality of channel structures in a second direction intersecting the first direction;
source/drain patterns on the semiconductor pattern and between the plurality of channel structures, each of the source/drain patterns including a first epitaxial layer having a first concentration of impurities and a second epitaxial layer on the first epitaxial layer and having a second concentration of impurities higher than the first concentration of impurities;
an insulating isolation layer on a lower surface of the semiconductor pattern;
a plurality of insulating isolation patterns on a lower surface of the insulating isolation layer in respective regions corresponding to the plurality of gate structures, the plurality of insulating isolation patterns extending toward the plurality of gate structures, respectively, and dividing the semiconductor pattern into a plurality of pattern regions;
a plurality of contact blocks on the lower surface of the insulating isolation layer and between the plurality of insulating isolation patterns;
a contact via extending through the insulating isolation layer and extending from at least one contact block among the plurality of contact blocks to a first source/drain pattern among the source/drain patterns, wherein the plurality of pattern regions includes a first pattern region penetrated by the contact via and a second pattern region not penetrated by the contact via;
a contact epitaxial layer between the first pattern region and the first source/drain pattern, and the contact via, and having a third concentration of impurities higher than the first concentration of impurities;
a metal-semiconductor compound layer between the contact epitaxial layer and the contact via, and including a same semiconductor element as a semiconductor element of the contact epitaxial layer; and
an interconnection structure on lower surfaces of the plurality of contact blocks and the plurality of insulating isolation patterns, and electrically connected to the at least one contact block.

15. The semiconductor device of claim 14, wherein impurities of the contact epitaxial layer include impurities having the same conductivity as a conductivity of impurities of an adjacent source/drain pattern of the source/drain patterns.

16. The semiconductor device of claim 14, wherein the first pattern region has a concentration of impurities higher than a concentration of impurities of the second pattern region.

17. The semiconductor device of claim 14, wherein each of the plurality of insulating isolation patterns is configured having a shape in which a first width, in the first direction, of a first portion adjacent to the interconnection structure is greater than a second width, in the first direction, of a second portion adjacent to the plurality of gate structures.

18. The semiconductor device of claim 14, wherein each of the plurality of contact blocks is configured having a shape in which a first width, in the first direction, of a first portion adjacent to the interconnection structure is less than a second width, in the first direction, of a second portion adjacent to the insulating isolation layer.

19. A semiconductor device, comprising:
a semiconductor pattern extending in a first direction;
a device isolation layer on opposing side surfaces of the semiconductor pattern extending in the first direction;
a plurality of channel structures on the semiconductor pattern and spaced apart from each other in the first direction;
a plurality of gate structures intersecting the plurality of channel structures in a second direction intersecting the first direction;
first and second source/drain patterns on the semiconductor pattern and between the plurality of channel structures;
an interlayer insulating layer on the device isolation layer and extending around the plurality of gate structures and the first and second source/drain patterns;
an insulating isolation layer on a lower surface of the semiconductor pattern;
a plurality of insulating isolation patterns on regions corresponding to the plurality of gate structures on a lower surface of the insulating isolation layer, the plurality of insulating isolation patterns extending in the insulating isolation layer toward the plurality of gate structures, respectively, wherein the semiconductor pattern is divided into a plurality of pattern regions by the plurality of insulating isolation patterns;
a plurality of contact blocks on the lower surface of the insulating isolation layer and between the plurality of insulating isolation patterns;
a contact via extending in the insulating isolation layer from a contact block adjacent to the plurality of contact blocks among the plurality of contact blocks to the first source/drain pattern, wherein the plurality of pattern regions includes a first pattern region penetrated by the contact via and a second pattern region not penetrated by the contact via, and the first pattern region is configured having a concentration of impurities higher than a concentration of impurities of the second pattern region;
an upper contact extending in the interlayer insulating layer and connected to the second source/drain pattern;
a metal-semiconductor compound layer between the first pattern region and the first source/drain pattern, and the contact via;
a first interconnection structure on the interlayer insulating layer and electrically connected to the upper contact; and
a second interconnection structure on lower surfaces of the respective plurality of contact blocks, the plurality of insulating isolation patterns and the device isolation layer and electrically connected to the contact block adjacent to the plurality of contact blocks.

20. The semiconductor device of claim 19, further comprising:
a contact epitaxial layer between the first pattern region and the first source/drain pattern and the metal-semiconductor compound layer,
wherein the contact epitaxial layer includes a same semiconductor element as a semiconductor element of the metal-semiconductor compound layer, and the contact epitaxial layer includes impurities of a same conductivity as a conductivity of impurities of the first source/drain pattern.
